(19) United States
(12) Patent Application Publication
(10) Pub. No.: US 2016/0104751 A1
(43) Pub. Date: Apr. 14, 2016

(54) HYBRID DISPLAY ASSEMBLY INCLUDING A SOLAR CELL

(71) Applicant: The Swatch Group Research and Development Ltd, Marin (CH)

(72) Inventor: Michel SAGARDOYBURU, Neuchatel (CH)

(73) Assignee: The Swatch Group Research and Development Ltd, Marin (CH)

(21) Appl. No.: 14/794,132

(22) Filed: Jul. 8, 2015

(30) Foreign Application Priority Data
Oct. 10, 2014 (EP) 14188413.0

(51) Int. Cl. H01L 27/32; G02F 1/133; G02F 1/13363; G02F 1/1335

(52) U.S. Cl. CPC H01L 27/3227; G02F 1/133536; G02F 1/13306; G02F 1/13363; H01L 27/3232; G02F 2001/13324; G02F 2001/133541; G02F 2001/133638

(57) ABSTRACT

A display assembly for a portable object includes a first, at least partially transparent, emissive display device located on the side of an observer, a second reflective display device and a solar cell being arranged, in that order, underneath the first emissive display device. The second reflective display device is capable of switching between a transparent state, in which the device does not display any information, and a reflective state, when activated.

This application claims priority from European Patent Application No. 14188413.0 filed 10 Oct. 2014, the entire disclosure of which is incorporated herein by reference.

### FIELD OF THE INVENTION

The present invention concerns a hybrid display assembly including a solar cell. More specifically, the present invention concerns such a display assembly including two superposed display devices underneath which is arranged a solar cell.

### BACKGROUND OF THE INVENTION

The readability of the information displayed by display devices such as liquid crystal display cells or organic light emitting diode display devices is very dependent on ambient lighting conditions. With some display devices, the displayed information can be read in good conditions in a lit environment, but is difficult to read in a dark environment. Conversely, other categories of display devices provide a good quality display in twilight or darkness, but are difficult to read in broad daylight.

By way of example, let us consider transflective liquid crystal display cells, that is to say liquid crystal display cells capable of displaying information that will be visible in daytime by means of a reflection phenomenon, and which will also be visible at night by transmission by using a backlighting device. Such transflective liquid crystal display cells are optimised to provide the best possible reflection of sunlight and thus to ensure good readability of the displayed information in bright ambient conditions. However, in order for such transflective liquid crystal display cells to be capable of the best possible reflection of sunlight, their transmission efficiency is greatly restricted. Thus, when the backlighting device is activated to allow the displayed information to be read in twilight, most of the light emitted by the backlighting device is lost in absorption phenomena. Energy efficiency is therefore mediocre. Further, the optical qualities of the information displayed by the liquid crystal cell are greatly dependent on the viewing angle.

As regards emissive display devices, such as organic light emitting diode display devices, these devices have superior optical qualities to those of liquid crystal display cells, since the optical qualities are not dependent on the viewing angle. Nonetheless, these high quality emissive display devices do not permit a reflective mode of operation. The information displayed thereby is thus very readable in twilight or darkness, but becomes difficult to read once observed outdoors. To overcome this problem, it is possible to increase the amount of current supplied to emissive display devices so as to increase the brightness of the light emitting diodes and thus ensure minimum readability. However, even in normal conditions of use, these emissive display devices use more power than a reflective liquid crystal cell. Their electrical power consumption is such that it is difficult to envisage keeping them permanently on, in particular when they are incorporated in a portable object of small dimensions, such as a wristwatch, whose only source of energy is a battery which is usually required to last for more than one year.

### SUMMARY OF THE INVENTION

It is thus an object of the present invention to overcome the aforementioned problems and others by providing a display assembly whose energy requirements can be satisfied even when it is incorporated in a portable object of small dimensions, such as a wristwatch, whose energy reserves are, however, limited. The present invention also provides a display assembly which operates in a satisfactory manner both in a well lit environment and in a dark environment.

To this end, the present invention concerns a display assembly for a portable object, this display assembly including a first, at least partially transparent, emissive display device located on the side of an observer, a second reflective display device and a solar cell being arranged, in that order, underneath the first emissive display device, the second reflective display device being capable of switching between a transparent state, when at rest, and a reflective state, when activated.

According to a complementary feature of the invention, the transparent emissive display device is fixed onto the reflective display device.

According to another feature of the invention, the transparent emissive display device is bonded onto the reflective display device by means of an adhesive film or a liquid adhesive layer.

As a result of these features, the present invention provides a display assembly for a portable object, such as a wristwatch, which operates in an optimum manner regardless of the ambient lighting conditions. In broad daylight, the information will preferably be displayed by the reflective display device. Indeed, this reflective display device, utilising a phenomenon of sunlight reflection to display information, is energy efficient. It can therefore remain permanently switched on and offers good readability of information. Conversely, in twilight or darkness, the information will be displayed by the emissive display device. Such an emissive display device uses less current than a reflective display device, but the information displayed thereby is visible at night or in darkness with very good optical properties which are notably independent of the viewing angle. Further, if this type of emissive display device is mainly used at night or in poorly lit environments, the electrical current consumption still remains limited, since it is unnecessary in such conditions to power it fully. On the contrary, low electrical power is sufficient to allow easy reading of the information. Thus, unlike a transflective liquid crystal display cell, which attempts to reach a compromise between the reflectivity of its reflective mode, and the electrical power consumption of its backlighting device in transmissive mode, the display assembly according to the invention proposes to combine two display devices, one purely reflective and the other purely emissive, without compromising the performance of either one of these two display devices. Further, by teaching that a solar cell is arranged underneath the two superposed display devices, the present invention allows integration of such an assembly in a portable object of small dimensions whose electrical energy reserves are necessarily limited. Indeed, it was observed that the amount of light that reached the solar cell through the set of two superposed display devices was sufficient to provide, by a phenomenon of photoelectric conversion, the amount of electrical energy necessary for operation of the two superposed display devices. Consequently, little or no demand is made on the electrical energy reserves of the portable object for operation of the two superposed display devices.

According to one embodiment of the invention, the first display device includes a transparent emissive display cell, and the second display device includes a twisted nematic, or super twisted nematic, or vertically aligned reflective liquid crystal display cell. The transparent emissive display cell may be either a transparent organic light emitting diode emissive display cell or a transparent inorganic emissive display cell.

According to a complementary feature of the invention, the organic light emitting diode display cell is arranged between a circular polarizer and a quarter-wave plate, the circular polarizer being placed on the side of the observer.

Addressing of the light emitting areas of the organic light emitting diode display cells is ensured by transparent electrodes, usually made with the aid of a metallic material or a metallic oxide. These electrodes thus quite often cause slight optical reflection phenomena which result in a degradation of contrast, which is detrimental to the readability of the information displayed by the organic light emitting diode display cells. To overcome this drawback, the present invention teaches arranging the organic light emitting diode display cell between a circular polarizer and a quarter-wave plate, the circular polarizer being placed on the side of the observer. Thus, one of the ambient light polarization components that penetrates the display assembly according to the invention is absorbed by the circular polarizer, whereas the other light polarization component is circularly polarized. When, on passing through the organic light emitting diode display cell, the circularly polarized ambient light is partially reflected by the transparent electrodes of the organic light emitting diode display cell, this reflected light undergoes a phase shift, which has the effect of transforming the circular polarization into a circular polarization in the opposite direction of rotation. Thus, when the reflected light passes through the circular polarizer again, it is absorbed thereby. In this manner, it is possible to eliminate stray light which is reflected onto the electrodes of the organic light emitting diode display cell, and to retain only the light that passes through the organic light emitting diode display cell without modification. Subsequently, the light is linearly polarized again after passing through the quarter-wave plate placed underneath the organic light emitting diode display cell and will eventually be absorbed or reflected by the reflective liquid crystal display cell depending upon whether a positive or negative contrast display is required.

### BRIEF DESCRIPTION OF THE DRAWINGS

Other features and advantages of the present invention will appear more clearly from the following detailed description of one embodiment of the display assembly according to the invention, this example being given solely by way of non-limiting illustration with reference to the annexed drawing, in which:

FIG. 1 is a schematic cross-section illustrating a display assembly according to the invention including a first at least partially transparent emissive display device situated on the side of an observer, a second reflective display device and a solar cell being arranged in that order underneath the first emissive display device.

FIG. 2 is a cross-section of an example embodiment of a display assembly according to the invention wherein the first display device is a transparent, emissive, organic light emitting diode display cell, and the second display device is a twisted nematic reflective liquid crystal display cell, a solar cell being arranged underneath this display assembly.

FIGS. 3A to 3D are schematic illustrations of the operating mode of the display assembly illustrated in FIG. 2 depending on whether the organic light emitting diode display cell and the twisted nematic liquid crystal display cell are active or passive.

FIG. 4 is a similar view of that of FIG. 2, wherein the second display device is a vertically aligned reflective liquid crystal display cell.

FIGS. 5A to 5D are schematic illustrations of the operating mode of the display assembly illustrated in FIG. 4 depending on whether the organic light emitting diode display cell and the vertically aligned liquid crystal display cell are active or passive.

FIG. 6 is a similar view to that of FIG. 2 except that, in order to remove stray reflections and thereby improve the display contrast, a circular polarizer, which is formed of a second absorbent polarizer and a first quarter-wave plate, is placed above the transparent organic light emitting diode display cell, on the side of the observer.

### DETAILED DESCRIPTION OF ONE EMBODIMENT OF THE INVENTION

The present invention proceeds from the general inventive idea which consists in providing a display assembly which is capable of displaying information in a readable manner both in broad daylight and in twilight or darkness and which has optimal electrical energy consumption. To achieve this object, the present invention teaches combining an emissive display device with a display device that is arranged to be capable of switching between a rest state in which it is transparent and an active state in which it is capable of reflecting ambient light. The emissive display device is typically an organic light emitting diode display cell, whereas the reflective display device is typically a liquid crystal display cell. For the display of information in broad daylight, use of the reflective display device is preferred, which, by the reflection of sunlight, can display information in a clear and readable manner with low electrical energy consumption. For the display of information in twilight or darkness, use of the emissive display device is preferred. Owing to its excellent optical properties, particularly in terms of contrast and colour reproduction, such an emissive display device makes it possible to display a large amount of information in a highly readable manner. In particular, the readability of the displayed information is not dependent on the viewing angle. Further, in twilight or darkness, it is possible to significantly reduce the energy consumption of such an emissive display device while ensuring good readability of the displayed information. There is therefore provided a display assembly that includes a reflective display device placed at the base of a stack and which is capable of permanently displaying information using very little energy, and an emissive display device, placed on the top of the stack and which is capable of displaying information on demand in a highly readable manner in twilight or darkness. It was also realised that, by arranging a solar cell underneath the two superposed display devices, by the effect of photoelectric conversion, the solar cell generated an electrical current sufficient to allow operation of the two superposed display devices. It is therefore possible to integrate such a display assembly in a portable object of small dimensions, such as a wristwatch whose electrical energy storage capacity is, however, limited.

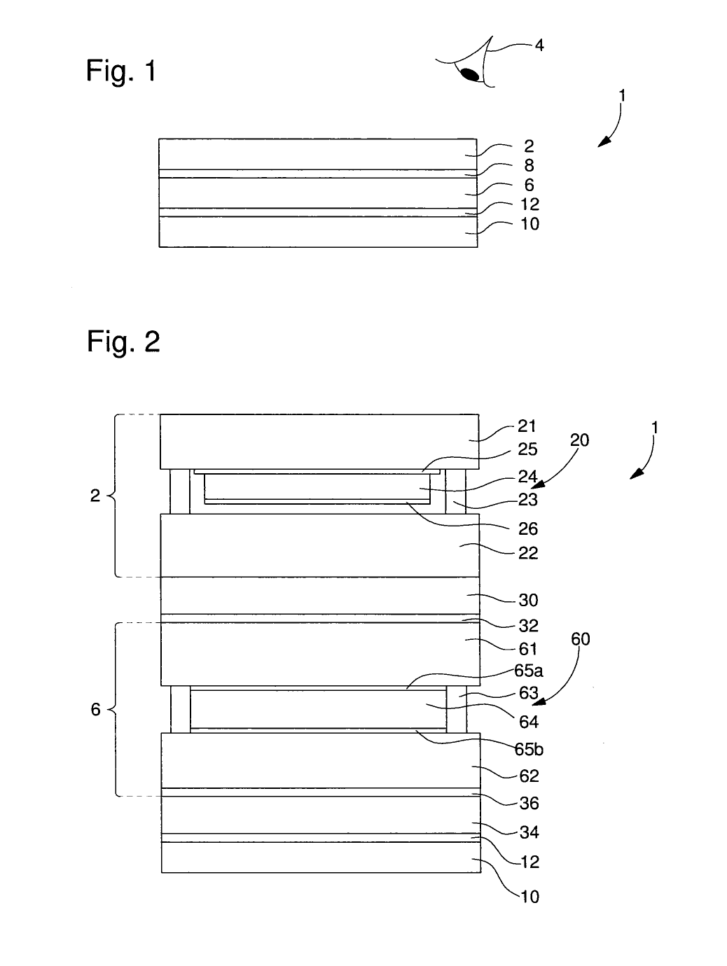

FIG. 1 is a schematic cross-section of a display assembly according to the invention. Designated as a whole by the general reference numeral 1, this display assembly includes a first, at least partially transparent, emissive display device 2 arranged on the side of an observer 4, and a second, also at least partially transparent, reflective display device 6, arranged underneath the first emissive display device 2. Within the meaning of the present invention, the first emissive display device 2 is capable of switching between a passive state in which it is at least partially transparent, and an active state in which it emits light to display information. The second reflective display device 6 is capable of switching between a passive state in which it is transparent and an active state in which it is capable of reflecting ambient light.

Preferably, but not essentially, first emissive display device 2 is bonded on second reflective display device 6 by means of a transparent adhesive layer 8. This transparent adhesive layer 8 may be formed of an adhesive film or of a liquid acrylic or silicon adhesive. The purpose of this transparent adhesive layer 8 is to prevent the problems of stray reflections which would occur if the two display devices 2, 6 were separated by an air layer and which would degrade the optical quality of display assembly 1 according to the invention.

Finally, a solar cell 10, capable of providing electrical energy by making use of the phenomenon of photoelectric conversion, is arranged underneath second reflective display device 6. Preferably, but in a non-limiting manner, solar cell 10 is bonded underneath second reflective display device 6 by means of a transparent adhesive layer 12.

In the following description, the invention will be described with reference to a transparent emissive organic light emitting diode type display cell. It will be understood, however, that this example is given purely by way of non-limiting illustration and that other types of transparent emissive display cells, such as inorganic transparent electroluminescent displays or “ELDs” may be envisaged without departing from the scope of the invention as defined by the annexed claims.

FIG. 2 is a detailed cross-sectional view of an example embodiment of display assembly 1 according to the invention, in the case where the first emissive display device 2 includes a transparent organic light emitting diode display cell 20, referred to hereafter as a TOLED display cell. Second reflective display device 6 includes a reflective twisted nematic (TN) liquid crystal display cell 60.

More specifically, TOLED display cell 20 includes a transparent substrate 21 made of glass or of a plastic material and an encapsulation cover 22 which extends parallel to and remote from transparent substrate 21. Transparent substrate 21 and encapsulation cover 22 are joined to each other by a sealing frame 23 which delimits a closed volume shielded from air and humidity to contain a stack of electroluminescent layers generally designated by the reference number 24. An upper transparent electrode 25, made for example of indium-tin oxide or ITO, and a lower transparent electrode 26, made for example using a metallic material such as aluminium or silver or a metallic oxide such as ITO or zinc-indium oxide, are structured on both sides of the stack of electroluminescent layers 24. These electrodes 25, 26, made of a metallic material, are slightly reflective. The transparent organic light emitting diode display cells are available either with direct addressing, in cases where they simply display icons or segments, or with passive matrix addressing in the case of a dot matrix display. In the case of a dot matrix display, it is also possible to use active matrix addressing combined with transparent thin film transistors (TFT) intended to control the current and which are arranged in display pixels.

On the other hand, reflective liquid crystal display 60 includes a front substrate 61 arranged on the side of the observer 4 and a rear substrate 62 which extends parallel to and remote from front substrate 61. Front substrate 61 and rear substrate 62 are joined to each other by a sealing frame 63 which delimits a sealed volume 64 for containing a liquid crystal whose optical properties are modified by application of a suitable voltage at a particular crosspoint between transparent electrodes 65a arranged on a lower face of front substrate 61 and transparent counter electrodes 65b arranged on an upper face of rear substrate 62. Electrodes 65a and counter electrodes 65b are made of a transparent electrically conductive material such as indium-zinc oxide or indium-tin oxide (ITO).

In the case of the present invention, any of the liquid crystal phases, such as twisted nematic (TN), super twisted nematic (STN) or vertically aligned (VA), may be envisaged. Likewise, all addressing schemes, such as direct addressing, active matrix addressing, or passive matrix multiplexing addressing may be envisaged.

An absorbent polarizer 30 is bonded on an upper surface of front substrate 61 of reflective liquid crystal display cell 60 by means of an adhesive layer 32. This adhesive layer 32 may be formed of an adhesive film or of a liquid adhesive. The adhesive used to bond absorbent polarizer 30 on reflective liquid crystal display cell 60 may be transparent or slightly diffusing depending on whether specular or diffuse reflection is required. Absorbent polarizer 30 may be, for example, an iodine or dye type polarizer.

A reflective absorbent polarizer 34 is bonded on a lower face of rear substrate 62 of reflective liquid crystal display cell 60 by means of an adhesive layer 36 which may be transparent or slightly diffusing depending on whether specular or diffuse reflection is required.

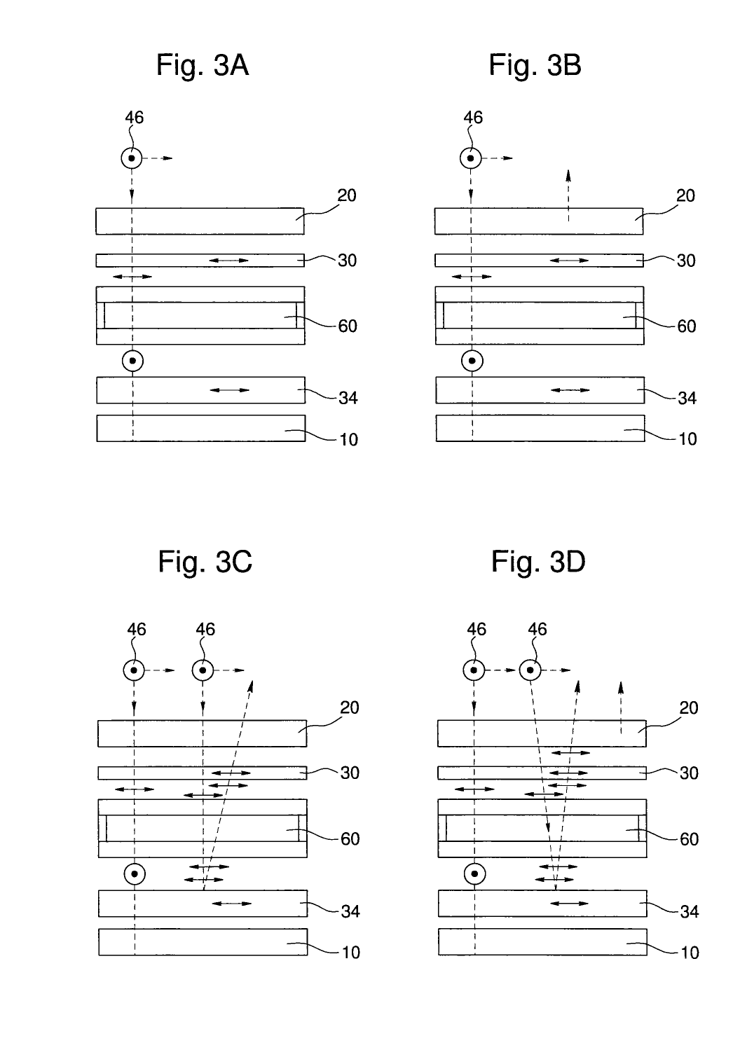

With reference to FIGS. 3A to 3D the operating principles of display assembly 1 according to the invention will now be examined depending on whether or not TOLED display cell 20 and reflective liquid crystal display cell 60 are in use. It will be assumed, purely by way of non-limiting illustration, that reflective liquid crystal display cell 60 is a twisted nematic (TN) liquid crystal cell and that the axis of transmission of absorbent polarizer 30 and the axis of reflection of reflective polarizer 34 are parallel.

In FIG. 3A, TOLED display cell 20 and TN reflective liquid crystal display cell 60 are both switched off. The ambient light, designated by the reference number 46, passes unchanged through TOLED display cell 20 and is then linearly polarized by absorbent polarizer 30. Ambient light 46 then undergoes a 90° rotation when it passes through TN reflective liquid crystal display cell 60, so that when it falls on reflective polarizer 34, its direction of polarization is perpendicular to the axis of reflection of reflective polarizer 34 and it thus passes through the latter before being absorbed by solar cell 10. Reflective TN liquid crystal display cell 60 thus appears dark when switched off, which means that the information that it will display will appear light on a dark background. The information display thus has a negative contrast. Of course, an information display with a positive contrast could be obtained simply by ensuring that the axis of transmission of polarizer 30 and the axis of reflection of reflective absorbent polarizer 34 are perpendicular. In such case, ambient light 46 only reaches the solar cell in the areas of TN reflective liquid crystal display cell 60 that are switched.

In FIG. 3B, TOLED display cell 20 is activated, whereas TN reflective liquid crystal display cell 60 is deactivated. The light emitted by TOLED display cell 20 reaches observer 4 unchanged, whereas TN reflective liquid crystal display cell 60 appears dark. The information displayed by TOLED display cell 20 therefore stands out on a dark background.

In FIG. 3C, TOLED display cell 20 is switched off, whereas TN reflective liquid crystal display cell 60 is activated. As already explained above, the non-switched areas of TN reflective liquid crystal display cell 60 appear dark. Conversely, in the switched areas of TN reflective liquid crystal display cell 60, ambient light 46 passes unchanged through these areas, so that ambient light 46 falls on reflective polarizer 34 with a parallel direction of polarization to the axis of reflection of reflective polarizer 34. Ambient light 46 is therefore reflected back and passes unchanged in succession through TN reflective liquid crystal display cell 60, absorbent polarizer 30 and TOLED display cell 20, so that it is perceptible to observer 4. The displayed information therefore appears light on a dark background.

In FIG. 3D, TOLED display cell 20 and TN reflective liquid crystal display cell 60 are both activated. The light emitted by TOLED display cell 20 is directly perceptible to observer 4. Ambient light 46 which passes through the non-switched areas of TN reflective liquid crystal display cell 60 is absorbed by solar cell 10 so that these areas appear dark. Finally, ambient light 46 which passes through the switched areas of TN reflective liquid crystal display cell 60 is reflected by reflective polarizer 34, so that these areas appear light.

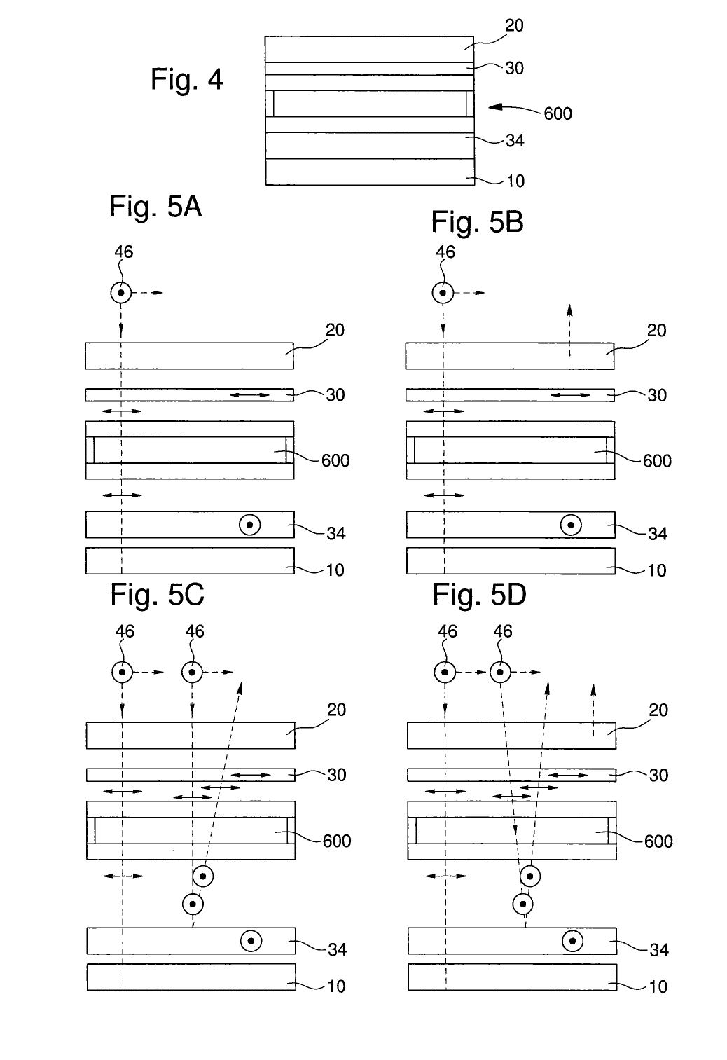

FIG. 4 is a cross-sectional view of an example embodiment of display assembly 1 according to the invention in the case where first display device 2 includes an emissive transparent organic light emitting diode display cell 20 which will be referred to hereafter as a TOLED display cell. Second display device 6 includes a vertically aligned (VA) reflective liquid crystal display cell 600.

With reference to FIGS. 5A to 5D the operating principles of display assembly 1 according to the invention will be examined depending on whether or not TOLED display cell 20 and VA reflective liquid crystal display cell 600 are in use. It will be assumed, purely by way of non-limiting illustration, that the axis of transmission of absorbent polarizer 30 and the axis of reflection of reflective polarizer 34 are perpendicular.

In FIG. 5A, TOLED display cell 20 and VA reflective liquid crystal display cell 600 are both switched off. The ambient light, designated by the reference number 46, passes unchanged in succession through TOLED display cell 20 and VA reflective liquid crystal cell 600, so that when it falls on reflective polarizer 34, its direction of polarization is perpendicular to the axis of reflection of reflective polarizer 34. It therefore passes unchanged therethrough and is finally absorbed by solar cell 10. Reflective TN liquid crystal display cell 60 thus appears dark when switched off, which means that the information that it will display will appear light on a dark background. The information display thus has a negative contrast. Of course, an information display with a positive contrast can be obtained simply by ensuring that the axis of transmission of absorbent polarizer 30 and the axis of reflection of reflective polarizer 34 are parallel.

In FIG. 5B, TOLED display cell 20 is activated, whereas VA reflective liquid crystal display cell 600 is deactivated. The light emitted by TOLED display cell 20 reaches observer 4 unchanged, whereas TN reflective liquid crystal display cell 60 appears dark. The information displayed by TOLED display cell 20 therefore stands out on a dark background.

In FIG. 5C, TOLED display cell 20 is switched off, whereas VA reflective liquid crystal display cell 600 is activated.

In a vertically aligned liquid crystal display cell, the alignment layers are oriented at 45° with respect to the axes of polarization of the polarizers. Moreover, the result of the product between the birefringence of the liquid crystal molecules and the distance between the front and rear substrates is selected so that, when the liquid crystal is switched, it behaves like a half-wave plate as regards the direction of polarization. Consequently, since this half-wave plate is placed at 45° with respect to the axis of polarization of the absorbent polarizer, it causes a 90° rotation of the direction of polarization of the light Thus ambient light 46 undergoes a 90° rotation when it passes through the switched areas of VA reflective liquid crystal display cell 600, so that when it falls on reflective polarizer 34, its direction of polarization is parallel to the axis of reflection of reflective polarizer 34 and it is therefore reflected by the latter. The ambient light 46 which passes through the non-switched areas of VA reflective liquid crystal display cell 600 is absorbed by solar cell 10. The displayed information is therefore light on a dark background, i.e. with a negative contrast.

In FIG. 5D, TOLED display cell 20 and TN reflective liquid crystal display cell 60 are both activated. The light emitted by TOLED display cell 20 is directly perceptible to observer 4. The ambient light 46 which passes through the non-switched areas of VA reflective liquid crystal display cell 600 is absorbed by solar cell 10 so that these areas appear dark. Finally, the ambient light 46 which passes through the switched areas of VA reflective liquid crystal display cell 600 is reflected by reflective polarizer 34, so that these areas appear light.

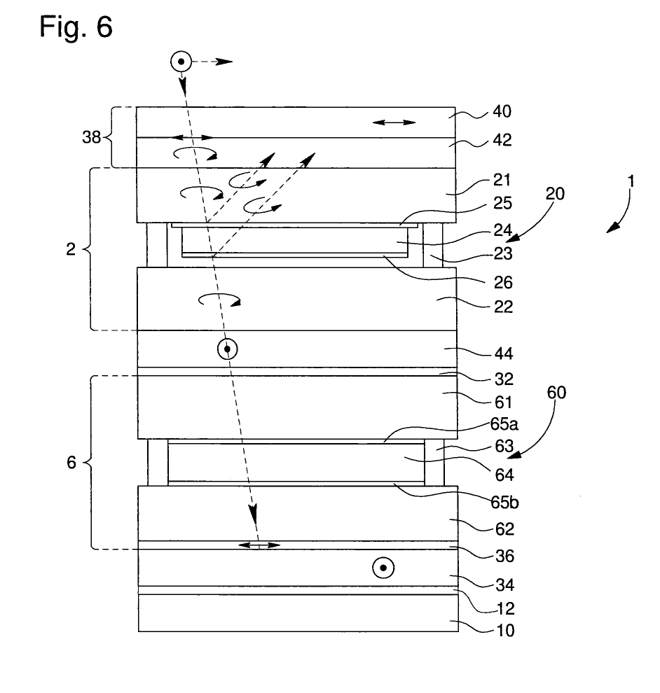

FIG. 6 is a similar view to that of FIG. 2 except that, in order to remove stray reflections and thereby improve the display contrast, a circular polarizer 38, which is formed of a second absorbent polarizer 40 and a first quarter-wave plate 42, is placed above the TOLED display cell 20, on the side of observer 4. Moreover, a second quarter-wave plate 44 is placed underneath TOLED display cell 20. This second quarter-wave plate 44 is parallel to first quarter-wave plate 42 or arranged at 90° relative to first quarter-wave plate 42. It will be assumed that the axis of transmission of second absorbent polarizer 40 and the axis of reflection of reflective polarizer 34 are perpendicular.

Addressing of the light emitting areas of the organic light emitting diode display cells is ensured by transparent electrodes, usually made with the aid of a metallic material or a metallic oxide. These electrodes thus quite often cause optical reflection phenomena which result in a degradation of contrast, which is detrimental to the readability of the information displayed by the organic light emitting diode display cells. To overcome this drawback, the present invention teaches arranging a circular polarizer 38 above TOLED display cell 20 and a second quarter-wave plate 44 underneath TOLED display cell 20. Thus, ambient light 46 which penetrates display assembly 1 according to the invention is linearly polarized by second absorbent polarizer 40, then circularly polarized by first quarter-wave plate 42. When, on passing through TOLED display cell 20, the circularly polarized ambient light 46 is partially reflected by the transparent upper and lower electrodes 25, 26 of TOLED display cell 20, this reflected light undergoes a phase shift, which has the effect of transforming the circular polarization into a circular polarization in the opposite direction of rotation. Thus, when the reflected light passes through circular polarizer 38 again, it is absorbed thereby. In this manner, it is possible to remove the stray light which is reflected on electrodes 25, 26 of TOLED display cell 20. The remaining ambient light 46 passes unchanged through TOLED display cell 20 and is then linearly polarized during its passage through second quarter-wave plate 44 in a direction perpendicular to the axis of transmission of second absorbent polarizer 40. Indeed, it is assumed that the first and second quarter-wave plates 42 and 44 are parallel to each other. During the passage of ambient light 46 through reflective liquid crystal display cell 60, the direction of polarization of ambient light 46 is rotated through 90°, so that it is eventually absorbed by solar cell 10.

The display is thus light on a dark background. In other words, display assembly 1 has a negative contrast. Indeed, in the switched areas of reflective liquid crystal display cell 60, ambient light 46 passes unchanged through reflective liquid crystal display cell 60, so that it falls on reflective polarizer 34 in a direction of polarization which is parallel to the axis of reflection of the latter. Ambient light 46 is therefore reflected by reflective polarizer 34, then passes unchanged through reflective liquid crystal display cell 60. Ambient light 46 is then circularly polarized by second quarter-wave plate 44, then passes unchanged through circular polarizer 38 and is perceptible to observer 4.

By way of variant, it is possible to envisage arranging the second quarter-wave plate 44 between reflective liquid crystal display cell 60 and reflective absorbent polarizer 34.

It goes without saying that this invention is not limited to the embodiments that have just been described and that various simple alterations and variants can be envisaged by those skilled in the art without departing from the scope of the invention as defined by the claims annexed to this patent application. It will be understood, in particular, that it is not strictly correct to say that ambient light passes unchanged through the reflective liquid crystal display cell or the TOLED display cell. In fact, when ambient light passes through these display cells, minimal stray light reflection phenomena always occurs. These stray reflections are, however, negligible within the scope of the present invention. It will also have been understood from the foregoing that it is also not strictly correct to speak of “transparent” electrodes. In fact, although made of a transparent, electrically conductive material, these electrodes are always very slightly reflective. The reflective liquid crystal display cell is selected from the group comprising twisted nematic liquid crystal display cells, super twisted nematic liquid crystal display cells and vertically aligned liquid crystal display cells. The reflective liquid crystal display cell may be a bistable display cell.

### LIST OF PARTS

Display assembly 1
First emissive display device 2
Observer 4
Second reflective display device 6
Transparent adhesive layer 8
Solar cell 10
Transparent adhesive layer 12
TOLED display cell 20
Transparent substrate 21
Encapsulation cover 22
Sealing frame 23
Stack of electroluminescent layers 24
Upper transparent electrode 25
Lower transparent electrode 26
Absorbent polarizer 30
Adhesive layer 32
Reflective absorbent polarizer 34
Adhesive layer 36
Circular polarizer 38
Second absorbent polarizer 40
First quarter wave plate 42
Second quarter wave plate 44
Ambient light 46
TN reflective liquid crystal display cell 60
Front substrate 61
Rear substrate 62
Sealing frame 63
Sealed volume 64
Transparent electrodes 65a
Transparent counter electrodes 65b
VA reflective liquid crystal display cell 600

1. A display assembly for a portable object, comprising:
a first, at least partially transparent, emissive display device located on the side of an observer, a second reflective display device and a solar cell being arranged, in that order, underneath the first emissive display device, the second reflective display device being capable of switching between a transparent state, in which the device does not display any information, and a reflective state, when activated.

2. The display assembly according to claim 1, wherein the emissive display device is bonded on the reflective display device.

3. The display assembly according to claim 2, wherein the emissive display device is bonded on the reflective display device by means of an adhesive film or a liquid adhesive layer.

4. The display assembly according to claim 1, wherein the first emissive display device includes a transparent emissive display cell, and wherein the second reflective display device includes a reflective liquid crystal display cell.

5. The display assembly according to claim 4, wherein the transparent emissive display cell is a transparent emissive organic light emitting diode display cell or a transparent emissive inorganic display cell.

6. The display assembly according to claim 5, wherein the transparent emissive organic light emitting diode display cell includes a stack of electroluminescent layers sandwiched between a transparent upper electrode and a transparent lower electrode.

7. The display assembly according to claim 5, wherein the reflective liquid crystal display cell is selected from the group comprising twisted nematic liquid crystal cells, super twisted nematic liquid crystal cells and vertically aligned liquid crystal display cells and wherein the addressing of these liquid crystal display cells may be of the direct type, the active matrix type or the passive matrix multiplexing type.

8. The display assembly according to claim 6, wherein the reflective liquid crystal display cell is selected from the group comprising twisted nematic liquid crystal cells, super twisted nematic liquid crystal cells and vertically aligned liquid crystal display cells and wherein the addressing of these liquid crystal display cells may be of the direct type, the active matrix type or the passive matrix multiplexing type.

9. The display assembly according to claim 5, wherein an absorbent polarizer is arranged on an upper face of the reflective liquid crystal display cell, and wherein a reflective polarizer is arranged underneath a lower face of the rear substrate of the reflective liquid crystal display cell.

10. The display assembly according to claim 6, wherein an absorbent polarizer is arranged on an upper face of the reflective liquid crystal display cell, and wherein a reflective polarizer is arranged underneath a lower face of the rear substrate of the reflective liquid crystal display cell.

11. The display assembly according to claim 7, wherein an absorbent polarizer is arranged on an upper face of the reflective liquid crystal display cell, and wherein a reflective polarizer is arranged underneath a lower face of the rear substrate of the reflective liquid crystal display cell.

12. The display assembly according to claim 8, wherein an absorbent polarizer is arranged on an upper face of the reflective liquid crystal display cell, and wherein a reflective polarizer is arranged underneath a lower face of the rear substrate of the reflective liquid crystal display cell.

13. The display assembly according to claim 5, wherein a circular polarizer, that is formed of an absorbent polarizer and a first quarter-wave plate, is placed above the transparent emissive organic light emitting diode display cell, and wherein a second quarter-wave plate is placed underneath the transparent emissive organic light emitting diode display cell.

14. The display assembly according to claim 6, wherein a circular polarizer, that is formed of an absorbent polarizer and a first quarter-wave plate, is placed above the transparent emissive organic light emitting diode display cell, and wherein a second quarter-wave plate is placed underneath the transparent emissive organic light emitting diode display cell.

15. The display assembly according to claim 7, wherein a circular polarizer, that is formed of an absorbent polarizer and a first quarter-wave plate, is placed above the transparent emissive organic light emitting diode display cell, and wherein a second quarter-wave plate is placed underneath the transparent emissive organic light emitting diode display cell.

16. The display assembly according to claim 8, wherein a circular polarizer, that is formed of an absorbent polarizer and a first quarter-wave plate, is placed above the transparent emissive organic light emitting diode display cell, and wherein a second quarter-wave plate is placed underneath the transparent emissive organic light emitting diode display cell.

17. The display assembly according to claim 9, wherein a circular polarizer, that is formed of an absorbent polarizer and a first quarter-wave plate, is placed above the transparent emissive organic light emitting diode display cell, and wherein a second quarter-wave plate is placed underneath the transparent emissive organic light emitting diode display cell.

18. The display assembly according to claim 10, wherein a circular polarizer, that is formed of an absorbent polarizer and a first quarter-wave plate, is placed above the transparent emissive organic light emitting diode display cell, and wherein a second quarter-wave plate is placed underneath the transparent emissive organic light emitting diode display cell.

19. The display assembly according to claim 11, wherein a circular polarizer, that is formed of an absorbent polarizer and a first quarter-wave plate, is placed above the transparent emissive organic light emitting diode display cell, and wherein a second quarter-wave plate is placed underneath the transparent emissive organic light emitting diode display cell.

20. The display assembly according to claim 12, wherein a circular polarizer, that is formed of an absorbent polarizer and a first quarter-wave plate, is placed above the transparent emissive organic light emitting diode display cell, and wherein a second quarter-wave plate is placed underneath the transparent emissive organic light emitting diode display cell.

21. The portable object including a display assembly according to claim 1.

22. The portable object according to claim 21, wherein the object is a wristwatch.
